(19) United States
(12) Patent Application Publication
(10) Pub. No.: US 2012/0163146 A1
(43) Pub. Date: Jun. 28, 2012

(54) METHOD AND APPARATUS FOR WRITING DATA TO OPTICAL STORAGE MEDIUM

(75) Inventors: Hsiang-ji Hsieh, Jhubei City (TW); You-wen Chang, Hsinchu City (TW); Shy-junn Hsiao, Taipei City (TW)

(73) Assignee: MEDIATEK INC., Hsin-Chu (TW)

(21) Appl. No.: 13/411,359

(22) Filed: Mar. 2, 2012

Related U.S. Application Data
(62) Division of application No. 12/581,103, filed on Oct. 16, 2009.
(60) Provisional application No. 61/144,972, filed on Jan. 15, 2009.

(51) Int. Cl. G11B 20/10; H03L 7/00; G11B 7/0045

(52) U.S. Cl. 369/59.12; 369/59.11; 327/141; 327/161; G9B/20.009; G9B/7.01

(57) ABSTRACT

A method and apparatus for writing data to an optical storage medium are disclosed. A write signal indicating power levels of a laser diode is generated by encoding and decoding codewords. The codewords are generated and decoded according to a specific requirement proposed by the present invention. By doing so, toggling (i.e. state changing) times occurring in channels transferring the codewords can be significantly reduced to avoid the problems of pulse distortion and disappearance in high frequency transmission. Alternatively, toggles appearing in the respective channels can be spread to avoid interference between the channels. Further, a phase adjustment device for adjusting a phase of each codeword is disclosed.

### CROSS REFERENCE TO RELATED APPLICATION

The present application is a divisional application of U.S. patent application Ser. No. 12/581,103, filed on Oct. 16, 2009, entitled “Method and apparatus for writing data to optical storage medium”, which claimed the benefit of the filing date under 35 U.S.C. §119(e) of a Provisional U.S. Patent Application No. 61/144,972, entitled “Optical Storage Medium Recording with Successive State Change Criterion”, filed on Jan. 15, 2009, which is incorporated by reference herein.

### TECHNICAL FIELD OF THE INVENTION

The present invention relates to recording data to an optical storage medium, more particularly, to generation of a write signal which is used to write data to the optical storage medium.

### BACKGROUND OF THE INVENTION

In current optical storage system, to write data to an optical storage medium such as a disk with a recording apparatus, the laser power of the recording apparatus is controlled by a write signal. The write signal is determined based on a write strategy. The writing laser power varies according to the write signal, which indicates the required laser power levels during the respective phases of writing.

Conventionally, the write signal is composed by several control signals. The composed write signal has different levels at different phases of writing so as to exhibit a required waveform to indicate the different required laser power levels for writing data. However, sometimes it is difficult to exactly form a perfect write signal based on the write strategy by composing the control signals since distortion of the control signals is likely to happen when transferring the control signals. To form the required waveform of the write signal, a control signal comprises one or more narrow pulses may have to be used. This increase the possibility of the write signal distortion.

Therefore, it will be highly satisfactory if a scheme for effectively forming an exact write signal can be provided.

### SUMMARY OF THE INVENTION

The present invention is to provide a method and apparatus for generating a required write signal by using codewords. The write signal is used to write data to an optical storage medium with proper power levels. By encoding data bits into codewords so as to form the write signal, toggling (i.e. state changing) times occurring in channels transferring the codewords can be significantly reduced as compared to the prior art, in which the control signals are accumulated to form the write signal. Therefore, the problems of pulse distortion and disappearance in high frequency transmission can be avoided. Alternatively, toggles appearing in the respective channels can be spread to avoid interference between the channels.

In accordance with one aspect of the present invention, a method for writing data to an optical storage medium is provided. The method comprises generating data bits to be written to the optical storage medium; encoding the data bits into a plurality of codewords, transferring the codewords via band-limited channels, respectively; receiving the transferred codewords; and decoding the codewords to generate a write signal of a laser diode, the write signal indicating power levels of the laser diode required for writing the data to the optical storage medium. Toggles of the codewords control power levels of the write signal for writing the data to follow a predetermined sequence and the codewords are encoded and decoded based on a requirement, according to the requirement, when a first toggle has appeared in one codeword, a second toggle is allowed to appear in the same codeword only when there is no neighboring toggle appearing in any other codeword within a predetermined time.

In accordance with another aspect of the present invention, an apparatus for writing data to an optical storage medium is provided. The apparatus comprises a non-return-to-zero-inverted (NRZI) generator for generating an NRZI signal containing data bits; a state controller for encoding the data bits of the NRZI signal to generate a plurality of codes; a plurality of state changers, each of the state changers receiving a code from the state controller to convert a level of an output of the state changer so as to generate a codeword; a plurality of channels for respectively transferring the codewords from the state changers; and a state decoder receiving the codewords transferred via the channels and decoding the codewords to generate the write signal indicating power levels required for writing the data to the optical storage medium, the laser diode being driven by the write signal to write the data bits to the optical storage medium with the power levels indicated by the write signal. Toggles of the codewords control power levels of a write signal of a laser diode for writing the data to follow a predetermined sequence the state controller encodes the data bits, and the state decoder decodes the codewords based on a requirement: after a first toggle has appeared in one codeword, a second toggle is allowed to appear in the same codeword only when there is no neighboring toggle appearing in any other codeword within a predetermined time.

In accordance with a further aspect of the present invention, an apparatus for writing data to an optical storage medium is provided. The apparatus comprises a data source generator for generating data bits of the data to be written to the optical storage medium; an encoder for encoding the data bits into a plurality of codewords; a plurality of channels for respectively transferring the codewords generated by the encoder; and a decoder receiving the codewords transferred via the channels and decoding the codewords to generate the write signal indicating power levels required for writing the data to the optical storage medium, the laser diode being driven by the write signal to write the data to the optical storage medium with the power levels indicated by the write signal. Toggles of the codewords control power levels of a write signal of a laser diode for writing the data to follow a predetermined sequence, and the encoder encodes the data bits and the decoder decodes the codewords based on a requirement, according to the requirement, when a first toggle has appeared in one codeword, a second toggle is allowed to appear in the same codeword only when there is no neighboring toggle appearing in any other codeword within a predetermined time.

The present invention also provides a phase adjustment device for adjusting a phase of a codeword. The phase adjustment device comprises an alignment adjuster for adjusting a phase of a signal (e.g. a codeword); and an alignment detector detecting the phase of the signal, generating a judge result indicating if the phase of the signal is correct and sending the judge result to the alignment adjuster. The alignment adjuster adjusts the phase of the signal according to the judge result. The alignment adjuster can adjust a rising edge and a falling edge of the signal by using different delays.

### BRIEF DESCRIPTION OF THE DRAWINGS

The present invention will be described in detail in conjunction with the appending drawings, in which:

FIG. 1 is a timing diagram showing control signals and a write signal generated from the control signals;

FIG. 2A shows a schematic diagram of the transmission of control signals, FIGS. 2B and 2C respectively show timing diagrams of the transmitted and received control signals;

FIGS. 3A and 3B show the timing diagrams of the received control signals in applications of a high speed optical storage system;

FIG. 4 is a timing diagram showing an example in which a write signal are generated based on control signals according to the prior art accumulation method;

FIG. 5 is a flow chart showing a method for writing data to an optical storage medium in accordance with the present invention;

FIG. 6A shows a schematic diagram of the transmission of two codewords generated in accordance the present invention, FIG. 6B is a timing diagram of the codewords, FIGS. 6C and 6D respectively show timing diagrams of the received codewords C11 and C12 in a worse condition and a worst condition;

FIG. 7 is a timing diagram showing an example in which a write signal is generated based on codewords generated according to SSCC (Successive State Change Criterion) of the present invention;

FIG. 8 is a timing diagram showing another example in which a write signal is generated based on codewords generated according to SSCC of the present invention;

FIG. 9 is a schematic block diagram showing an apparatus for writing data to an optical storage medium in accordance with an embodiment of the present invention;

FIG. 10 is a schematic block diagram showing an apparatus for writing data to an optical storage medium in accordance with another embodiment of the present invention;

FIG. 11 is a schematic block diagram showing an apparatus for writing data to an optical storage medium in accordance with still another embodiment of the present invention;

FIG. 12 is a schematic block diagram showing an apparatus for writing data to an optical storage medium in accordance with a different embodiment of the present invention;

FIG. 13 is a schematic block diagram showing an apparatus for writing data to an optical storage medium, which is modified from the apparatus of FIG. 12;

FIG. 14 is a schematic block diagram showing an apparatus for writing data to an optical storage medium, which is another modification of the apparatus of FIG. 12;

FIG. 15A is a schematic block diagram showing an alignment adjuster and an alignment detector implementing a phase adjustment device, FIG. 15B is a timing chart showing codewords and a feedback signal in the phase adjustment device, and FIG. 15C is a time chart showing that a rising edge and falling edge of a codeword are adjusted with different delays;

FIG. 16 is a flow chart showing a process of alignment adjustment for the codewords operated by the structure of FIG. 15A;

FIG. 17 is a schematic diagram showing an example of two codewords under the first requirement of SSCC;

FIG. 18 is a schematic diagram showing an example of three codewords under the first requirement of SSCC;

FIG. 19 is a schematic diagram showing an example of two codewords under the second requirement of SSCC;

FIG. 20 is a schematic diagram showing an example of three codewords under the second requirement of SSCC;

FIG. 21 is a schematic diagram showing an example of two codewords under the requirement of SSCC II; and

FIG. 22 is a schematic diagram showing an example of three codewords under the requirement of SSCC II.

### DETAILED DESCRIPTION OF THE INVENTION

As known in this field, to write data to a disk, the data is encoded to generate an internal EFM (eight-to-fourteen modulation) signal. A write strategy unit of a laser diode driver (LDD) controller generates control signals (e.g. EFM1, EFM2, EFM3) based on the internal EFM signal and predetermined period durations, details thereof will be further described later. A laser diode driver (LDD) receives the control signals to generate a write signal (i.e. a laser power signal) accordingly.

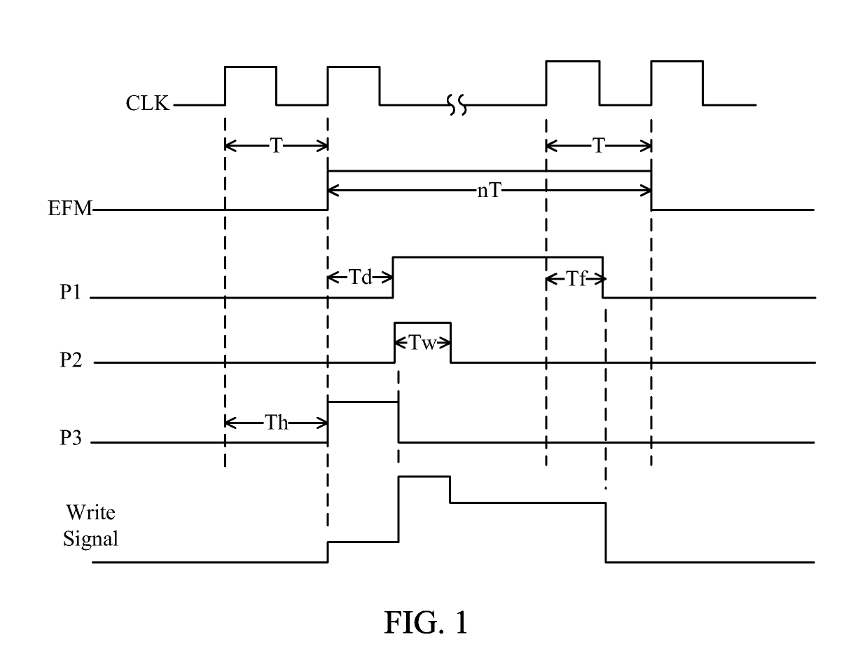

FIG. 1 is a timing diagram showing the control signals and the write signal mentioned above. The internal EFM signal is synchronized to a system clock, the period thereof is T. The period duration Td defines a delay from the rising edge of the internal EFM signal to a rising edge of the first control signal P1. The period duration Tw defines the pulse width of the second control signal P2. The period duration Tf defines time between the rising edge of the system clock CLK one period T prior to the falling edge of the internal EFM signal and the falling edge of the first control signal P1. The period duration Th defines time between the rising edge of the system clock one clock period prior to the rising edge of the internal EFM signal and the rising edge of the third control signal P3. According to FIG. 1, the write signal (i.e. laser power signal) is obtained by directly accumulating the first control signal P1, the second control signal P2 and the third control signal P3.

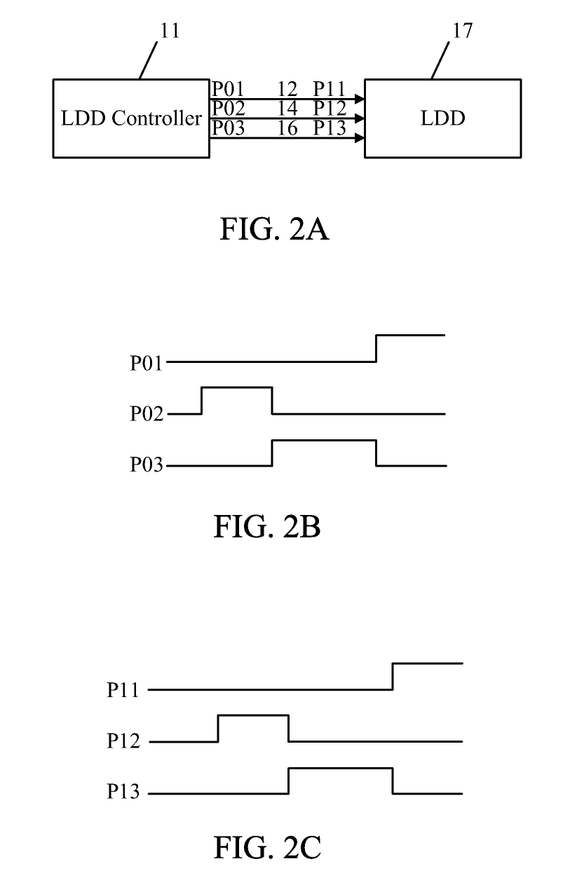

As mentioned, the control signals are generated in the LDD controller and transferred to the LDD. FIG. 2A shows a schematic diagram of the transmission of the control signals, FIGS. 2B and 2C respectively show timing diagrams of the transmitted and received control signals. As shown, transmitted control signals P01, P02, P03 are transmitted from an LDD controller 11, and transferred via respective channels such as transmission lines 12, 14, 16. The LDD controller 11 transmits each control signal at one end of a corresponding transmission line, and an LDD 17 receives the respective control signals at the other ends of the transmission lines 12, 14, 16. For the sake of descriptive convenience, the received control signals are indicated by P11, P12, and P13.

The transmission lines 12, 14, 16 are band-limited due to the intrinsic resistances and capacitances. At low frequencies, the waveforms of the received control signals P11, P12, P13 are substantially of the same shapes as those of the transmitted control signals P01, P02, P03 with a time delay as shown in the drawings. However, as the speed of optical storage system grows up, the transferred signals will be distorted or even disappear on the channels.

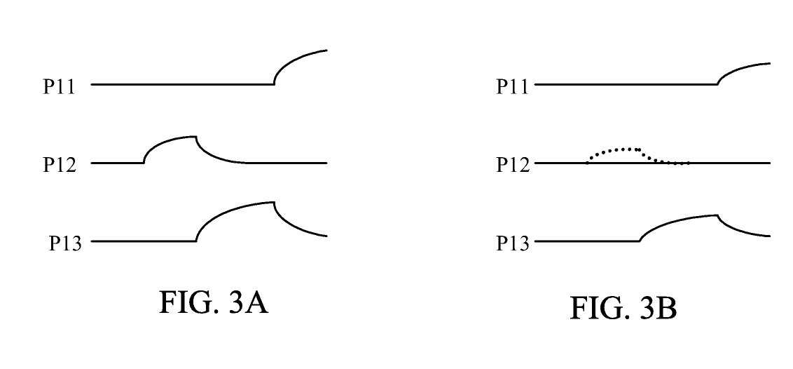

FIGS. 3A and 3B show the timing diagrams of the received control signals in applications of a high speed optical storage system. As shown in FIG. 3A, the control signals are distorted, the received control signals P11, P12, P13 have significantly different waveforms from the transmitted control signals P01, P02, P03 of FIG. 2B. In this case, the control signal(s) may disappear at the LDD side. As shown in FIG. 3B, the received control signal P12 disappears. When the pulse width of the control signal is narrow, the situation becomes more critical.

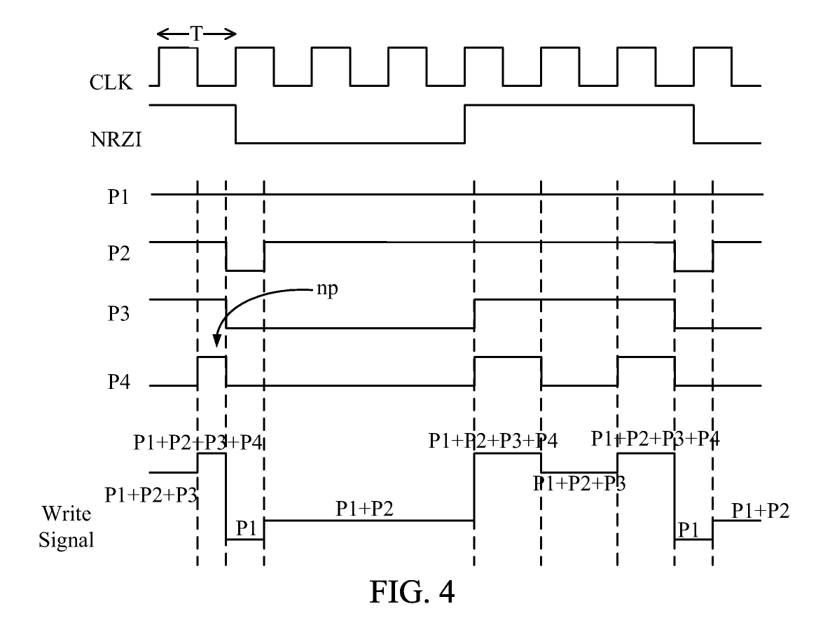

FIG. 4 is a timing diagram showing an example in which a write signal is generated based on control signals (e.g. EFM signals) according to the accumulation method. As known in this field, data is encoded to generate an NRZI signal which contains data bits based on the system clock CLK with a period of T. Control signals are generated from the NRZI signal. As shown in the drawing, the write signal is obtained by directly accumulating four control signals P1, P2, P3 and P4. In order to achieve the required waveform of the write signal, there may be narrow pulses appearing in the control signals, such as a narrow pulse ‘np’ in the control signal P4. The duration of ‘np’ is even shorter than the pulse width (i.e. period of T) of the clock CLK. As described above, the narrow pulses may disappear or be distorted when the speed of the optical storage system is high.

Thus, a write signal is not obtained by accumulating several control signals in the embodiment. Instead, a plurality of codewords are encoded according to data bits of data to be written to an optical storage medium, and the required write signal can be obtained by decoding the combination of the codewords. To reduce toggling count, encoding of the codewords is preferable to follow a “successive state change criterion (hereinafter, SSCC)”. According to the SSCC, successive toggles (i.e. state changes) in a codeword are allowed to appear only after a toggle has appeared in any other channel or after a predetermined time while the first one of the successive toggles appears.

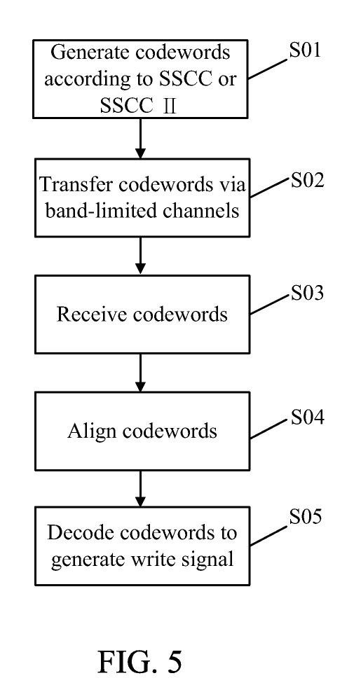

FIG. 5 is a flow chart showing a method for writing data to an optical storage medium in one embodiment of the present invention. In the method, data bits of data to be written to an optical storage medium are encoded to generate a plurality of codewords according to SSCC or modified SSCC (i.e. SSCC II, which will be described later) proposed by the present invention in step S01. The data can be firstly encoded into an NRZI signal containing data bits, for example, and then encoded as codewords. The codewords are transferred via band-limited channels in step S02 and are received in step S03. In step S05, the write signal is generated by decoding the codewords. The write signal is then used to drive a laser diode to write data to the optical storage medium. The method can further comprise a step S04 before the write signal is generated. In step S04, the codewords are adjusted to be aligned with each other.

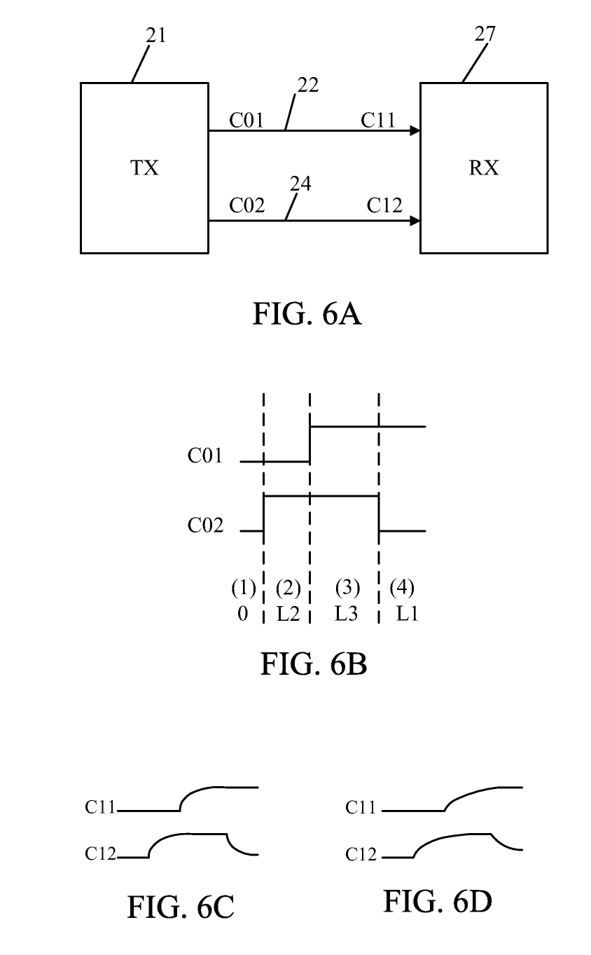

FIGS. 6A˜6D show an exemplification of the present invention. FIG. 6A shows a schematic diagram of the transmission of two codewords. The two codewords are transmitted from a transmitting side 21 and received at a receiving side 27 respectively via two band-limited channels 22 and 24, which are transmission lines, for example. For the sake of describing convenience, the transmitted codewords are indicated as C01 and C02, while the received codewords are indicated as C11 and C12. FIG. 6B is a timing diagram of the codewords C01 and C02. In this embodiment, assumed the required write signal (not shown) should have a level of 0 in the first duration (1), a level of L2 in the second duration (2), a level of L3 in the third duration (3), and a level of L1 in the fourth duration (4). In this embodiment, gray code scheme is used. The codeword “00” represents the level of 0, “01” represents the level of L2, “11” represents the level of L3, and “10” represents the level of L1, then the codewords C01 and C02 are both low in the first duration (1), codeword C01 is low and codeword C02 is high in the second duration (2), codeword C01 and codeword C02 are both high in the third duration (3), codeword C01 is high and codeword C02 is low in the fourth duration (4). By decoding the combinations of the received codewords C11 and C12, the required write signal can be obtained. FIGS. 6C and 6D respectively show timing diagrams of the received codewords C11 and C12 in a worse condition. As can be seen, although the waveforms of the received codewords C11 and C12 are deformed, the pulses are still distinguishable.

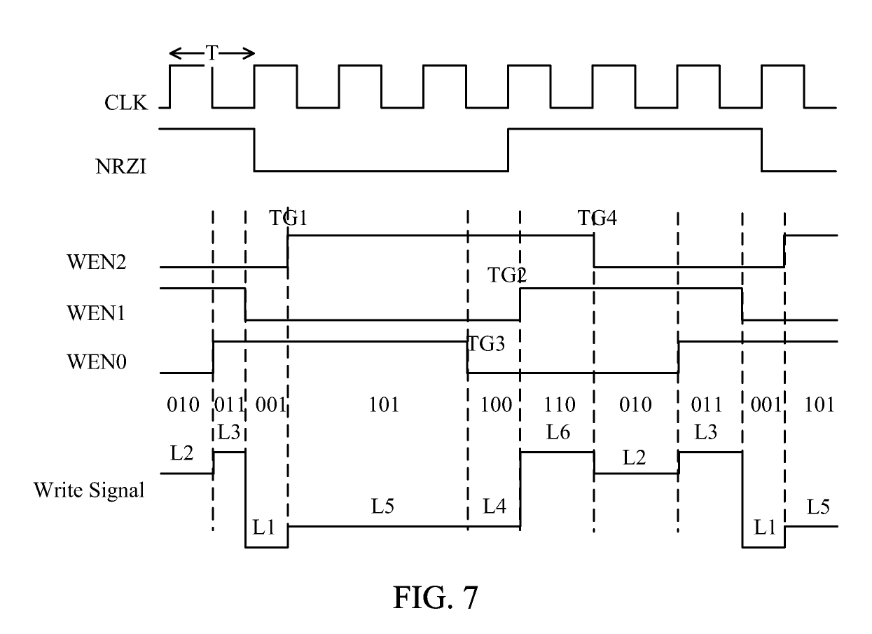

FIG. 7 is a timing diagram showing an embodiment in which a write signal is derived from codewords that are generated according to the first requirement of SSCC of present invention. That is, after a toggle (i.e. the signal level changes) appears in one codeword, a successive toggle is allowed to appear in the same codeword only when a toggle has appeared in any other codeword. For example, after a toggle TG1 at a rising edge of a codeword WEN2 appears, only when another toggle TG2 at a rising edge of another codeword WEN™ or another toggle TG3 at a falling edge of a further codeword WEN0 has appeared, a successive toggle TG4 at a falling edge of the same codeword WEN2 can appear. In this embodiment, the write signal to be generated is the same as that in FIG. 4. Data is encoded to generate an NRZI signal, which contains data bits, based on a clock CLK with a cycle period of T. The NRZI signal is then encoded according to SSCC by using Gray code scheme to generate a plurality of codewords, such as codeword WEN0, codeword WEN1, and codeword WEN2.

As seen, the write signal actually has four power levels, such as L1, L2, L3 (L6=L3), and L4 (L5=L4). However, in order to achieve a situation in which only one bit toggle appears at a time to follow gray code scheme, the data bits are encoded to generate three codewords WEN0, WEN1, WEN2. It is known that three codewords are able to represent eight power levels. The power levels are mapped to a sequence codes which meet Gray code encoding scheme, for example, 010→011→001→101→100→110→010→011→001→101. Each combination of the bit values (e.g. 1 or 0) of the three codewords WEN0, WEN1, WEN2 at the same time maps to a specific power level. For example, 001 indicates a level L1, 010 indicates L2, 011 indicates L3, 100 indicates L4, 101 indicates L5, and 110 indicates L6. Since we use eight combinations of the three codewords to represent the actual four power levels, some of the power levels are the same. For example, L4 equals to L5, L3 equals to L6. As can be seen in the drawing, by using the method of the present application, the same write signal can be obtained by using codewords without narrow pulses. It means that the codewords generated by implementing the present invention have no narrow pulse, thus the write signal can be exactly obtained by decoding the codewords, even if the write signal must have a narrow pulse. The present invention reduces the toggle rate (or transmission bandwidth) for each transmission channel. Therefore, the pulses of the respective codewords will be neither severely distorted nor disappear.

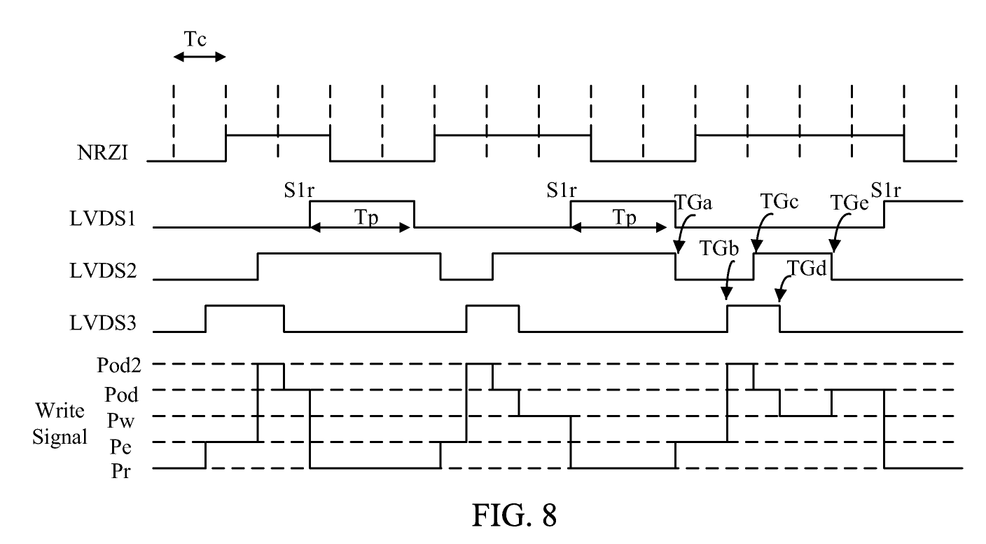

FIG. 8 is a timing diagram showing another embodiment in which a write signal is derived from codewords that are generated according to the second requirement of SSCC of the present invention. That is, there must be a predetermined time between successive toggles for the same codeword. Data is encoded to generate an NRZI signal, which contains data bits. The NRZI signal is then encoded according to SSCC to generate a plurality of codewords. In this embodiment, three codewords LVDS1, LVDS2, LVDS3 are generated so as to form the required write signal. In this drawing, T_{C} indicates a period of a clock.

In this embodiment, the rising edge S1r of the codeword LVDS1 controls the write power of the write signal to go back to the level Pr. After two clock cycles (i.e. 2×T_{C}), codeword LVDS1 is pulled to low. Between two rising edges of LVDS1, each toggle (e.g. TGa˜TGe) of codeword LVDS2 or codeword LVDS3 causes the write power of the write signal to follow a predetermined sequence of Pe, Pod2, Pod, Pw, Pod, . . . until the rising edge S1r of codeword LVDS1 appears again, then the write power of the write signal is back to Pr. Each of Pr, Pe, Pw, Pod, Pod2 indicates a specific power level. That is, the power levels indicated by the write signal are controlled by the toggles of the respective codewords. According to SSCC, two successive toggles can both appear in codeword LVDS1, codeword LVDS2 or codeword LVDS3 only when a predetermined period of time T_{P} has elapsed since the first one of the two successive toggles appears. In this example, T_{P} has a duration of two clock cycles (i.e. T_{P}=2×T_{C}). It can be seen from the drawing that none of the codewords LVDS1, LVDS2, LVDS3 has a narrow pulse.

To avoid the toggles in the respective codewords transferred on the channels to be interfered with each other, a second criteria SSCC II is proposed. According to the requirement of SSCC II, a toggle is allowed to appear in a codeword only when no neighboring toggle appears in any other codeword within a predetermined time.

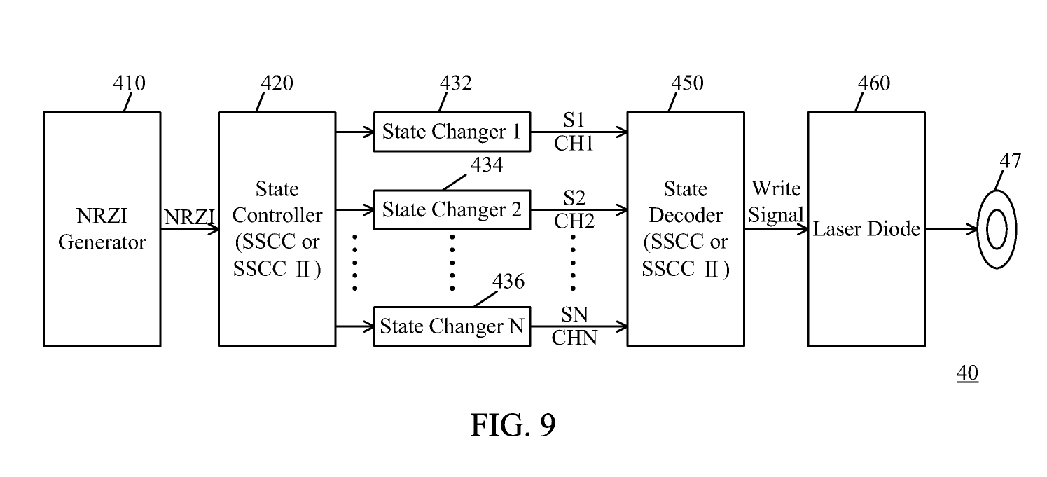

FIG. 9 is a schematic block diagram showing an apparatus 40 for writing data to an optical storage medium in accordance with an embodiment of the present invention. The apparatus 40 includes an NRZI generator 410 for encoding data to be written to an optical storage medium 470 into an NRZI signal, wherein the NRZI signal contains data bits. The NRZI signal is passed to a state controller 420. The state controller 420 encodes the NRZI signal according to SSCC or SSCC II proposed by the present invention based on a predetermined writing strategy to generate a plurality of codes. The codes are respectively sent to a plurality of state changers (e.g. “state changer 1” 432, “state changer 2” 434 to “state changer N” 436) to generate the same number of codewords. Each state changer is used to convert a level (e.g. from low to high or from high to low) of an output thereof according to the code from the state controller 420, and thus generate a codeword correspondingly. The codewords are indicated by S1, S2, . . . , SN. The codewords are respectively transferred via band-limited channels (e.g. transmission lines) CH1, CH2, . . . , CHN and received by a state decoder 450. The state decoder 450 receives the codewords S1 to SN and decodes the combinations of the codewords according to SSCC or SSCC II, depending on which is used in encoding the codewords, to generate a write signal. The write signal is used to drive a laser diode 460 so that the laser diode 460 writes the data to the optical storage medium 470 with proper power levels.

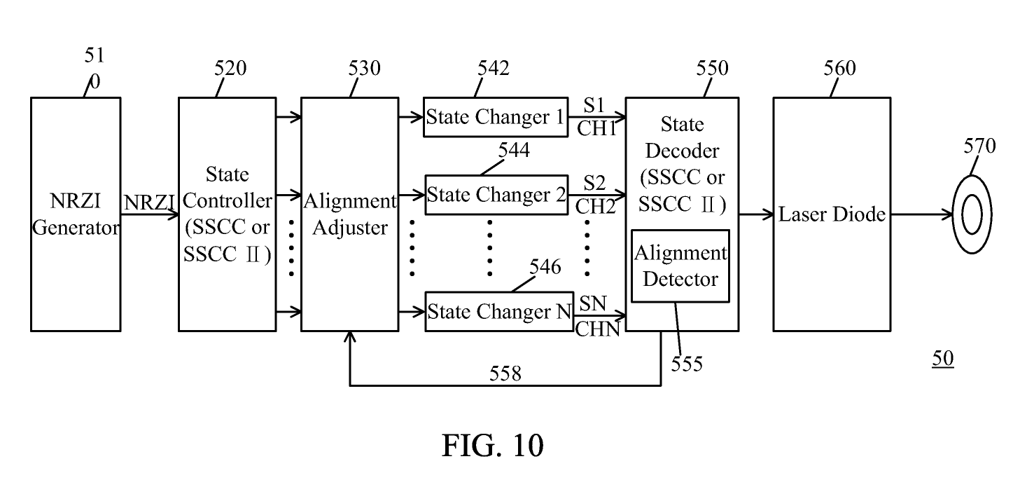

FIG. 10 is a schematic block diagram showing an apparatus 50 for writing data to an optical storage medium in accordance with another embodiment of the present invention. Most of the components of the apparatus 50 are the same as those with the same appellations of the apparatus 40. As the apparatus 40, the apparatus 50 comprises an NRZI generator 510, a state controller 520, state changers 1 to N indicated by reference numbers 542, 544, 546, a state decoder 550 and a laser diode 560. These components are similar to those of the apparatus 40, and therefore the descriptions thereabout are omitted herein to avoid redundancy. In the present embodiment, a mechanism for aligning codewords is provided. By aligning the codewords for reducing the signal mismatch among the codewords S1 to SN, the write signal can be generated more accurately. The apparatus 50 has an alignment adjuster 530 provided between the state controller 520 and the state changers 542, 543 . . . 546. The alignment adjuster 530 adjusts to align codes generated from the state controller 520. In addition, an alignment detector 555 is provided in the state decode 550. The alignment detector 555 checks the codewords, which are output from the state changers and transferred via the band-limited channels CH1 to CHN, to judge if the received codewords are aligned with each other. The judge result will be fed back to the alignment adjuster 530 via a feedback line 558. The alignment adjuster 530 may further adjust phases of the codes according to the judge result. The alignment adjuster 530 can also be provided at other positions. The alignment adjuster 530 and the alignment detector 555 can be considered as a phase adjustment device.

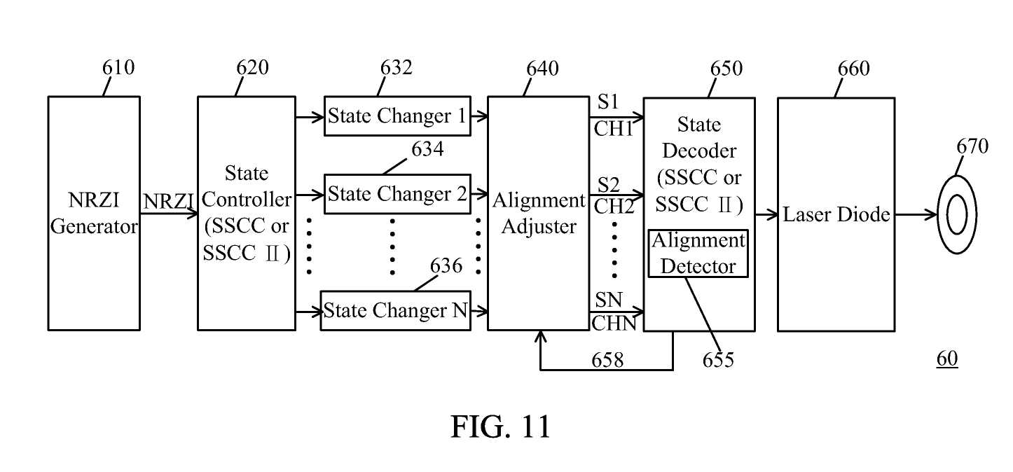

FIG. 11 is a schematic block diagram showing an apparatus 60 for writing data to an optical storage medium in accordance with still another embodiment of the present invention. The apparatus 60 is similar the apparatus 50. The apparatus 60 comprises an NRZI generator 610, a state controller 620, state changers 1 to N indicated by reference numbers 632, 634, 636, a state decoder 650 and a laser diode 660. The state decoder 650 of the apparatus 60 also has an alignment detector 655 as the state decoder 550 of the apparatus 50. The difference is that an alignment adjuster 640 is provided behind the state changers 632, 634 . . . 636 rather than before them. The alignment adjuster 640 adjusts codewords output from the state changers to align them. The adjusted codewords are transmitted to the state decoder 650 via band-limited channels CH1 to CHN. The alignment detector 655 checks the codewords to judge if they are aligned with each other. The judge result is fed back to the alignment adjuster 640 via a feedback line 658. The alignment adjuster 640 may further adjust phases of the codewords according to the judge result. The alignment adjuster 640 and the alignment detector 655 can be considered as a phase adjustment device.

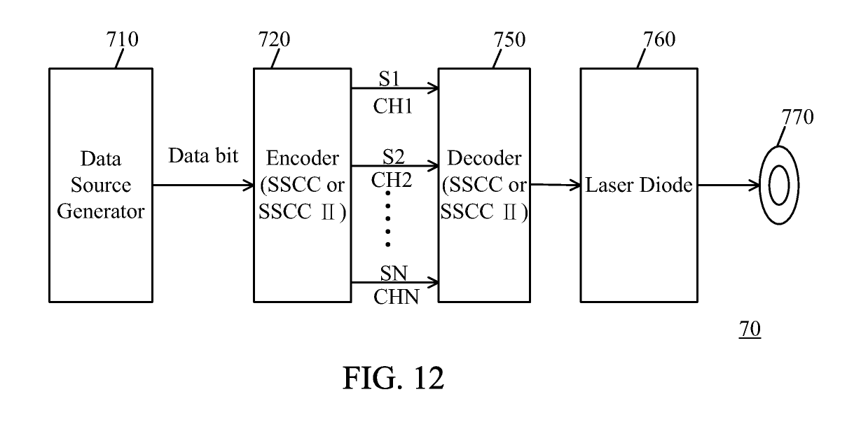

The present invention uses encoding technique to generate codewords, and to generate a write signal by decoding the codewords. Accordingly, it is possible that the NRZI generator is omitted. NRZI encoding (or any other encoding) and the codeword encoding can be done at the same time by the same encoder. FIG. 12 is a schematic block diagram showing an apparatus 70 for writing data to an optical storage medium in accordance with a different embodiment of the present invention. The apparatus 70 comprises a data source generator 710 for generate data bits for data to be written to an optical storage medium 770. An encoder 720 encodes the data bit into a plurality of codewords according to SSCC or SSCC II proposed by the present invention and optionally any other encoding scheme (e.g. NRZI) necessary for the optical storage medium 770. The codewords are respectively transferred to a decoder 750 via band-limited channels CH1 to CHN. The decoder 750 decodes the codewords according to SSCC (or SSCC II) and the used encoding scheme (e.g. NRZI, if any) to generate a write signal to drive a laser diode 760 so that the laser diode 760 records the data bits to the optical storage medium 770 with proper power levels.

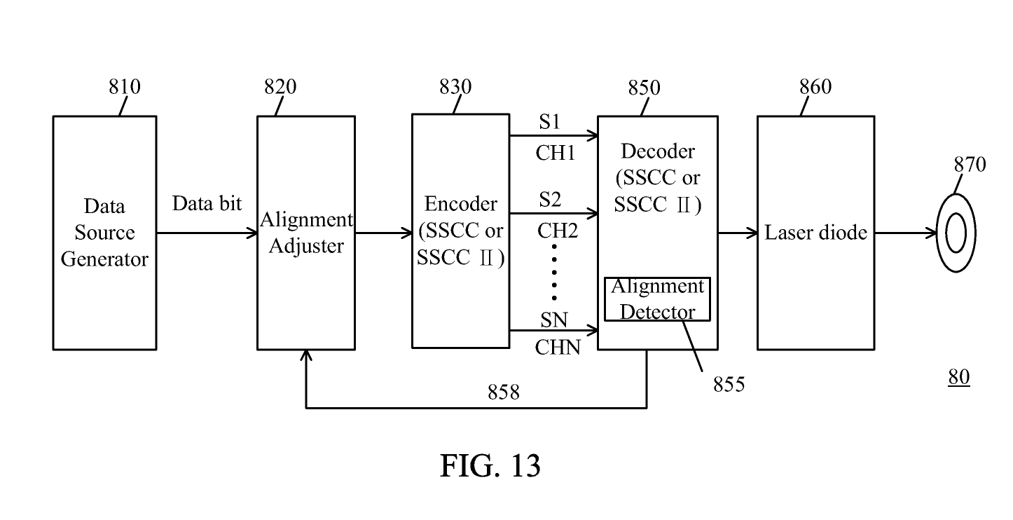

FIG. 13 is a schematic block diagram showing an apparatus 80 for writing data to an optical storage medium, which is modified from the apparatus 70 described above. Similar to the apparatus 70, the apparatus 80 comprises a data source generator 810, an encoder 830, a decoder 850 and a laser diode 860. In addition, the apparatus 80 has an alignment adjuster 820 provided before the encoder 830 to adjust the data bits so that codewords output by the encoder 830 can be aligned with each other. The decoder 850 has an alignment detector 855 for checking codewords transferred via the band-limited channels CH1 to CHN to judge if the received codewords are aligned with each other. The judge result will be fed back to the alignment adjuster 820 via a feedback line 858. The alignment adjuster 820 may further adjust the data bits according to the judge result. The alignment adjuster 820 can also be provided at other positions.

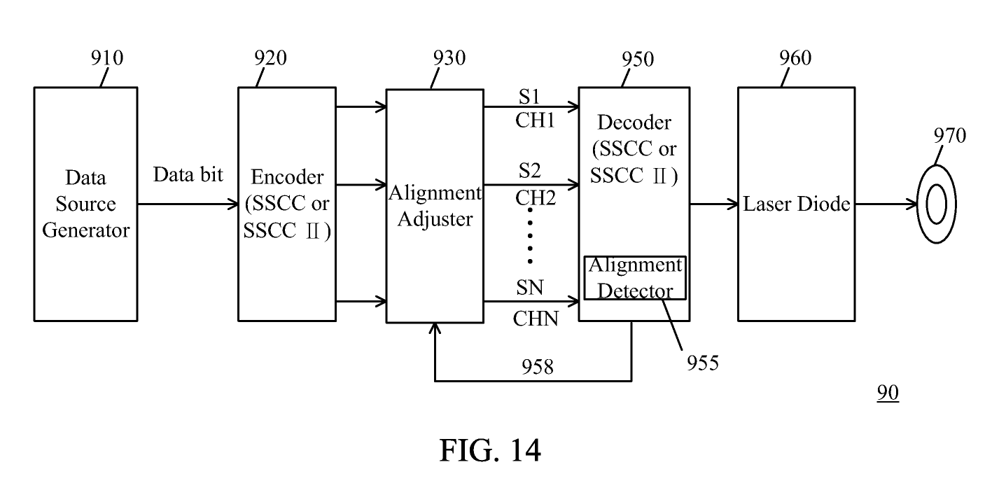

FIG. 14 is a schematic block diagram showing an apparatus 90 for writing data to an optical storage medium, which is another modification of the apparatus 70 described above. Similar to the apparatus 70, the apparatus 90 comprises a data source generator 910, an encoder 920, a decoder 950 and a laser diode 960. In addition, the apparatus 90 has an alignment adjuster 930 provided behind the encoder 920 to adjust codewords output by the encoder 920 so that the codewords can be aligned with each other. The decoder 950 has an alignment detector 955 for checking codewords transferred via the band-limited channels CH1 to CHN to judge if the received codewords are aligned with each other. The judge result will be fed back to the alignment adjuster 930 via a feedback line 958. The alignment adjuster 930 may further adjust the codewords according to the judge result.

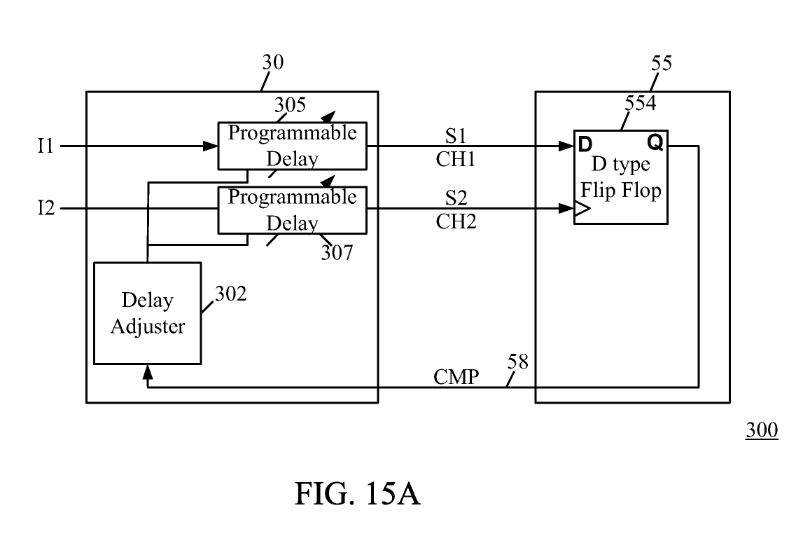

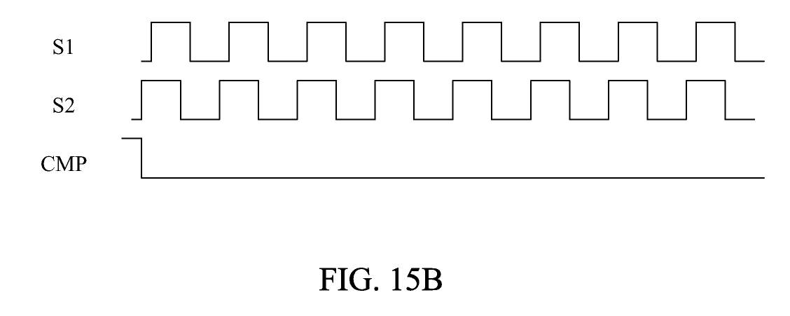

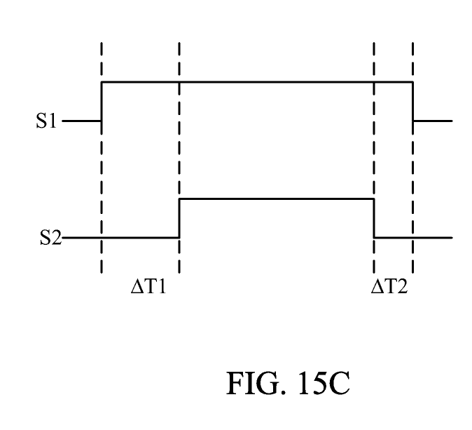

FIGS. 15A and 15B show an implementation of the phase adjustment device described above, wherein FIG. 15A is a schematic block diagram showing a phase adjustment device 300 including an alignment adjuster 30 and an alignment detector 55, and FIG. 15B is a timing chart showing codewords S1, S2 and a feedback signal CMP (i.e. a judge result) in the phase adjustment device 300. A situation of two channels CH1, CH2 is described herein as an example. The alignment adjuster 30 has a delay adjuster 302 and two programmable delay units 305, 307. The number of the programmable delay units is corresponding to the number of the channels and the number of codewords. The alignment adjuster 30 receives two unadjusted codewords, which are indicated by I1 and I2. The unadjusted codewords I1, I2 are respectively sent to the programmable delay units 305, 307. The delay adjuster 302 controls the programmable delay units 305, 307 to advance or postpone I1 or I2 so as to align the codewords with each other. The two codewords which have been adjusted and are output from the alignment adjuster 30 are indicated by S1 and S2.

As shown in FIG. 15B, the alignment detector 55 finds that the codeword S1 lags the codeword S2 in this case, and therefore codeword S1 should be advanced or codeword S2 should be postponed (left hand side represents the earlier time). The alignment detector 55 has a comparison unit such as a D type flip flop (D type FF) 554. The D type FF 554 compares the phases of the codewords S1 and S2 to judge if the phases of the codewords S1 and S2 are aligned with each other, and generates a judge result CMP. The judge result CMP is sent to the delay adjuster 302 via a feedback line 58. The delay adjuster 302 is able to know whether the calibration for the alignment of the phases of the codewords S1 and S2 has been done or not, and know how to adjust the phases of the codewords S1 or S2 according to the judge result CMP.

The phase adjustment device 300 described herein is used to align the codewords of plural codewords transferred via different channel. Moreover, the phase adjustment device 300 may adjust the rising edge and falling edge (i.e. the phase) of the codeword with different delays as required. FIG. 15C shows an application example, in which a rising edge and a fall edge of the codeword S2 are respectively adjusted with different delays. As show in the drawing, the codeword S2 is aligned with codeword S1 by respectively adjusting the rising edge and the falling edge with delays AT1 and AT2, and the AT2 can be different from AT1. Thus the phase adjustment device 300 can be used for a situation in which only one codeword is adjusted and transferred via a single channel.

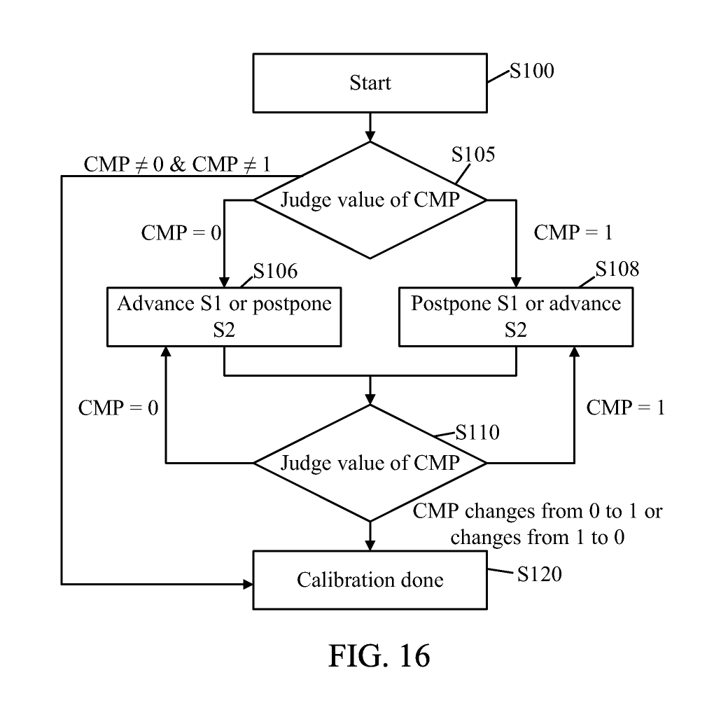

FIG. 16 is a flow chart showing a process of alignment adjustment for the codewords operated by the implement of FIG. 15A. The process starts at step S100. In step S105, the alignment detector 55 receives and compares S1 and S2, and outputs a judge result CMP. The judge result CMP is sent to the alignment adjuster 30. The alignment adjuster 30 checks the value of the signal CMP. For example, if CMP=0, it means that S1 lags with respect to S2. Then the alignment adjuster 30 advances S1 or postpones S2 in step S106. If CMP=1, it means that S1 leads with respect to S2. Then the alignment adjuster 30 postpones S1 or advances S2 in step S108. In step 110, the alignment detector 55 compares S1 and S2 again and outputs a new judge result CMP. If CMP keeps unchanged, the process goes back to step S106 or step S108 to further adjust S1 or S2. That is, if it is determined that CMP equals to 0 in step S105, the process goes to step S106, and it is determined that CMP keeps to be 0 in step S110, then the process goes back to step S106. If it is determined that CMP equals to 1 in step S105, the process goes to step S108, and it is determined that CMP keeps to be 1 in step S110, then the process goes back to step S108. If the value of the signal CMP changes from 0 to 1 or changes from 1 to 0, it means that the calibration has been done (step S120). Alternatively, if the value of CMP is neither 0 nor 1 in step S105, it means that S1 and S2 have been already aligned, then the process jumps to step S120.

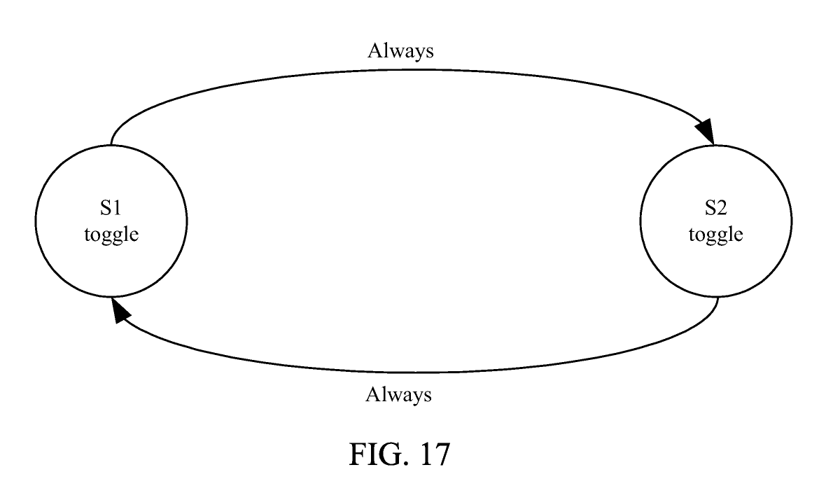

For better understanding of SSCC and SSCC II, some examples will be described with reference to FIG. 17 to FIG. 22. FIG. 17 is a schematic diagram showing an example of two codewords S1 and S2 under the first requirement of SSCC. The first requirement of SSCC defines: after a toggle of a codeword has appeared, a successive toggle is allowed to appear in the same codeword (or the same channel) only after a toggle has appeared in another codeword (or another channel). As shown in FIG. 17, after the codeword S1 has a toggle, the next toggle must appear in the codeword S2, and vice versa. In the drawing, the term “always” means that the process is a universal set.

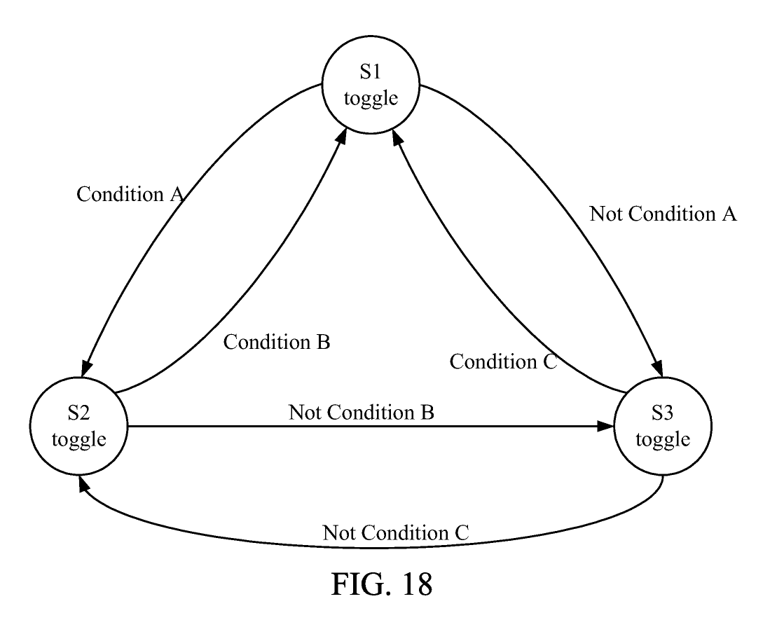

FIG. 18 is a schematic diagram showing an example of three codewords S1, S2 and S3 under the first requirement of SSCC. After S1 has a toggle, when a condition A is met, the next toggle can appear in S2, otherwise, the next toggle should appear in S3. Condition A can be any suitable condition for encoding the codewords, so are the conditions B, C . . . , mentioned later. After S2 has a toggle, when a condition B is met, the next toggle can appear in S1, otherwise, the next toggle should appear in S3. After S3 has a toggle, when a condition C is met, the next toggle can appear in S1, otherwise, the next toggle should appear in S2.

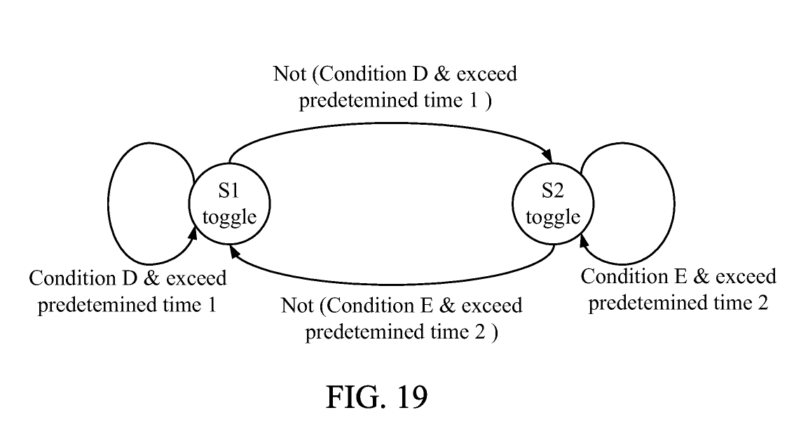

FIG. 19 is a schematic diagram showing an example of two codewords S1 and S2 under the second requirement of SSCC. The second requirement of SSCC defines: after a toggle of a codeword has appeared, a successive toggle is allowed to appear in the same codeword (or the same channel) only after a predetermined time has elapsed. As shown in FIG. 19, after the codeword S1 has a toggle, the next toggle is allowed to appear in S1 only when the following two limitations are both satisfied: (1) a condition D is met; and (2) a predetermined time 1 has elapsed. If not the two limitations are both satisfied, the next toggle should appear in S2. On the other hand, after the codeword S2 has a toggle, the next toggle is allowed to appear in S2 only when the following two limitations are satisfied: (1) a condition E is met; and (2) a predetermined time 2 has elapsed. If not the two limitations (1) and (2) are both satisfied, the next toggle should appear in S1. The predetermined time 1 and the predetermined time 2 can be the same, or different from each other.

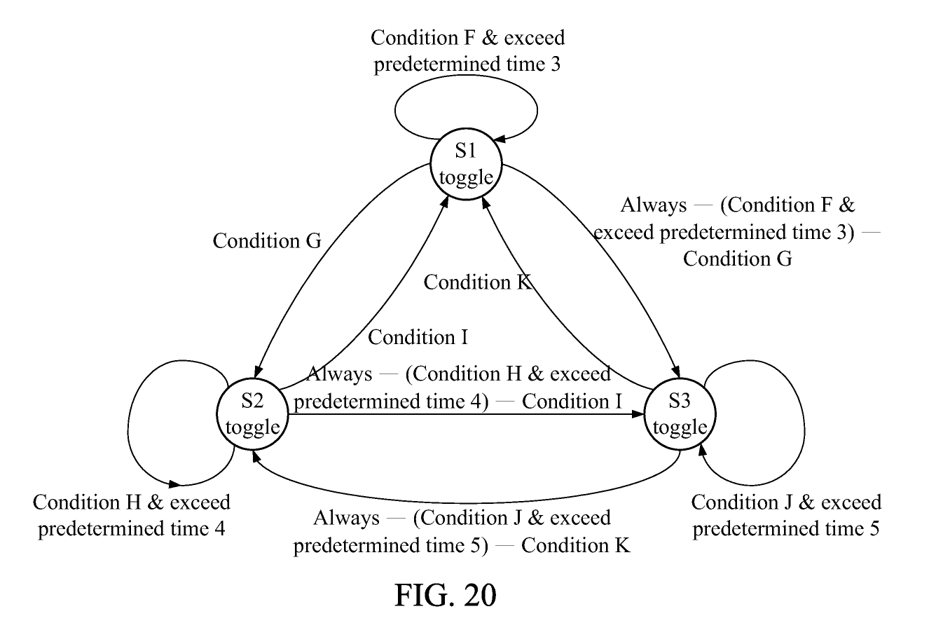

FIG. 20 is a schematic diagram showing an example of three codewords S1, S2 and S3 under the second requirement of SSCC. As shown in FIG. 20, after the codeword S1 has a toggle, the next toggle is allowed to appear in S1 only when the following two limitations are satisfied: (1) a condition F is met; and (2) a predetermined time 3 has elapsed. If not the two limitations are both satisfied, the next toggle should appear in S2 or S3. Under such a circumstance, if a condition G is met, the next toggle should appear in S2. Otherwise, the next toggle will appear in S3. After the codeword S2 has a toggle, the next toggle is allowed to appear in S2 only when the following two limitations are satisfied: (1) a condition H is met; and (2) a predetermined time 4 has elapsed. If not the two limitations (1) and (2) are both satisfied, the next toggle should appear in S1 or S3. Under such a circumstance, if a condition I is met, the next toggle should appear in S1. Otherwise, the next toggle will appear in S3. After the codeword S3 has a toggle, the next toggle is allowed to appear in S3 only when the following two limitations are satisfied: (1) a condition J is met; and (2) a predetermined time 5 has elapsed. If not the two limitations (1) and (2) are both satisfied, the next toggle should appear in S1 or S2. Under such a circumstance, if a condition K is met, the next toggle should appear in S1. Otherwise, the next toggle will appear in S2.

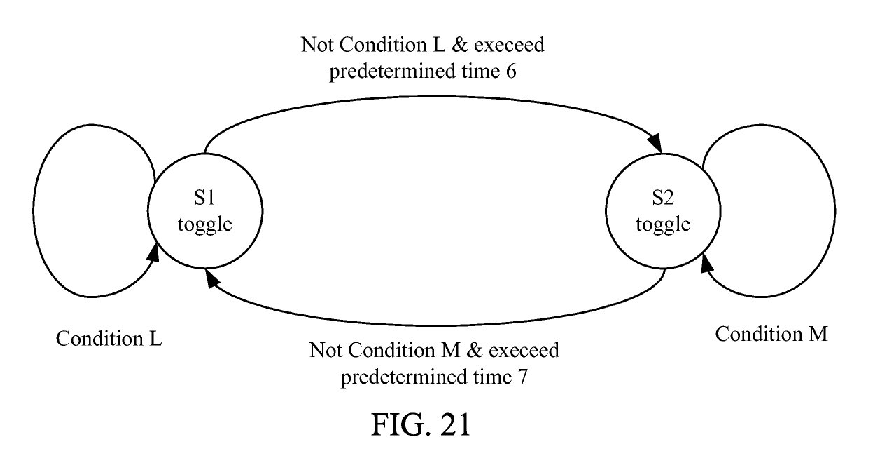

FIG. 21 is a schematic diagram showing an example of two codewords S1 and S2 under the requirement of SSCC II. The requirement of SSCC II defines: when a toggle of a codeword has appeared, another toggle is allowed to appear in any other codeword after a predetermined time has elapsed. As shown in FIG. 21, after the codeword S1 has a toggle, the next toggle is allowed to appear in S1 only when a condition L is met. When the condition L is not satisfied and a predetermined time 6 has elapsed, the next toggle can appear in S2. After the codeword S2 has a toggle, the next toggle is allowed to appear in S2 only when a condition M is met. When the condition M is not satisfied and a predetermined time 7 has elapsed, the next toggle can appear in S1.

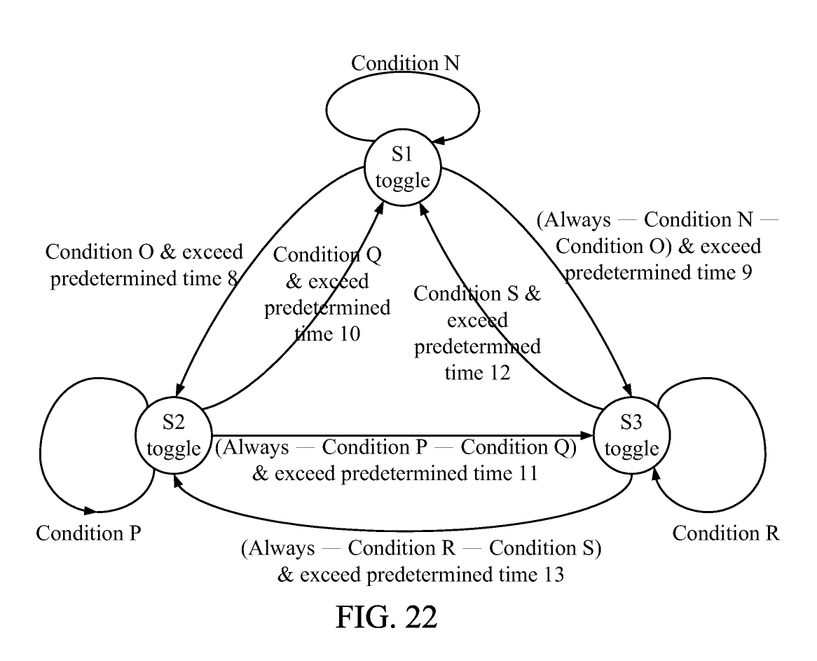

FIG. 22 is a schematic diagram showing an example of three codewords S1, S2 and S3 under the requirement of SSCC II. As shown in FIG. 22, after the codeword S1 has a toggle, the next toggle is allowed to appear in S1 only when a condition N is met. When a condition O is met and a predetermined time 8 has elapsed, the next toggle may appear in S2. When neither the condition N nor the condition O is satisfied, and a predetermined time 9 has elapsed, the next toggle can appear in S3. After the codeword S2 has a toggle, the next toggle is allowed to appear in S2 only when a condition P is met. When a condition Q is met and a predetermined time 10 has elapsed, the next toggle may appear in S1. When neither the condition P nor the condition Q is satisfied, and a predetermined time 11 has elapsed, the next toggle can appear in S3. After the codeword S3 has a toggle, the next toggle is allowed to appear in S3 only when a condition R is met. When a condition S is met and a predetermined time 12 has elapsed, the next toggle may appear in S1. When neither the condition R nor the condition S is satisfied, and a predetermined time 13 has elapsed, the next toggle can appear in S2.

While the preferred embodiments of the present invention have been illustrated and described in detail, various modifications and alterations can be made by persons skilled in this art. The embodiment of the present invention is therefore described in an illustrative but not restrictive sense. It is intended that the present invention should not be limited to the particular forms as illustrated, and that all modifications and alterations which maintain the spirit and realm of the present invention are within the scope as defined in the appended claims.

What is claimed is:

1. A method for writing data to an optical storage medium, the method comprising:
generating data bits to be written to the optical storage medium;
encoding the data bits into a plurality of codewords,
transferring the codewords via band-limited channels, respectively;
receiving the transferred codewords; and
decoding the codewords to generate a write signal of a laser diode, the write signal indicating power levels of the laser diode required for writing the data to the optical storage medium,
wherein toggles of the codewords control power levels of the write signal for writing the data to follow a predetermined sequence and the codewords are encoded and decoded based on a requirement, according to the requirement, when a first toggle has appeared in one codeword, a second toggle is allowed to appear in the same codeword only when there is no neighboring toggle appearing in any other codeword within a predetermined time.

2. The method of claim 2, further comprising a step of aligning the codewords before decoding the codewords.

3. An apparatus for writing data to an optical storage medium, the apparatus comprising:
a non-return-to-zero-inverted (NRZI) generator for generating an NRZI signal containing data bits;
a state controller for encoding the data bits of the NRZI signal to generate a plurality of codes;
a plurality of state changers, each of the state changers receiving a code from the state controller to convert a level of an output of the state changer so as to generate a codeword;
a plurality of channels for respectively transferring the codewords from the state changers; and
a state decoder receiving the codewords transferred via the channels and decoding the codewords to generate the write signal indicating power levels required for writing the data to the optical storage medium, a laser diode being driven by the write signal to write the data bits to the optical storage medium with the power levels indicated by the write signal,
wherein toggles of the codewords control power levels of a write signal of the laser diode for writing the data to follow a predetermined sequence, the state decoder decodes the codewords based on a requirement: after a first toggle has appeared in one codeword, a second toggle is allowed to appear in the same codeword only when there is no neighboring toggle appearing in any other codeword within a predetermined time.

4. The apparatus of claim 3, further comprising:
an alignment adjuster provided between the state controller and the state changers for adjusting the codes generated by the state controller so as to align the codewords generated by the state changers; and
an alignment detector detecting the codewords generated by the state changers to judge if the codewords are aligned with each other,
wherein the alignment detector generates a judge result indicating if the codewords are aligned with each other, the judge result is sent to the alignment adjuster, and the alignment adjuster adjusts the codes according to the judge result.

5. The apparatus of claim 4, wherein the alignment adjuster determines to adjust which one of the codes according to the judge result.

6. The apparatus of claim 3, further comprising:
an alignment adjuster provided between the state changers and the state decoder for adjusting the codewords generated by the state changers so as to align the codewords; and
an alignment detector detecting the codewords generated by the state changers to judge if the codewords are aligned with each other,
wherein the alignment detector generates a judge result indicating if the codewords are aligned with each other, the judge result is sent to the alignment adjuster, and the alignment adjuster adjusts the codewords according to the judge result.

7. The apparatus of claim 6, wherein the alignment adjuster determines to adjust which one of the codewords according to the judge result.

8. An apparatus for writing data to an optical storage medium with required power levels, the apparatus comprising:
a data source generator for generating data bits of the data to be written to the optical storage medium;
an encoder for encoding the data bits into a plurality of codewords;
a plurality of channels for respectively transferring the codewords generated by the encoder; and
a decoder receiving the codewords transferred via the channels and decoding the codewords to generate the write signal indicating power levels required for writing the data to the optical storage medium, a laser diode being driven by the write signal to write the data to the optical storage medium with the power levels indicated by the write signal,
wherein toggles of the codewords control power levels of a write signal of the laser diode for writing the data to follow a predetermined sequence, and the encoder encodes the data bits and the decoder decodes the codewords based on a requirement, according to the requirement, when a first toggle has appeared in one codeword, a second toggle is allowed to appear in the same codeword only when there is no neighboring toggle appearing in any other codeword within a predetermined time.

9. The apparatus of claim 8, further comprising:
an alignment adjuster provided between the data source generator and the encoder for adjusting the data bits generated by the data source generator so as to align the codewords generated by the encoder; and
an alignment detector detecting the codewords generated by the encoder to judge if the codewords are aligned with each other,
wherein the alignment detector generates a judge result indicating if the codewords are aligned with each other, the judge result is sent to the alignment adjuster, and the alignment adjuster adjusts the data bits according to the judge result.

10. The apparatus of claim 9, wherein the alignment adjuster determines how to adjust the data bits according to the judge result.

11. The apparatus of claim 8, further comprising:
an alignment adjuster provided between the encoder and the decoder for adjusting the codewords generated by the encoder so as to align the codewords; and
an alignment detector detecting the codewords generated by the encoder to judge if the codewords are aligned with each other,
wherein the alignment detector generates a judge result indicating if the codewords are aligned with each other, the judge result is sent to the alignment adjuster, and the alignment adjuster adjusts the codewords according to the judge result.

12. The apparatus of claim 11, wherein the alignment adjuster determines to adjust which one of the codewords according to the judge result.

13. A phase adjustment device, comprising:
an alignment adjuster for adjusting a phase of a signal; and
an alignment detector detecting the phase of the signal, generating a judge result indicating if the phase of the signal is correct, and sending the judge result to the alignment adjuster,
wherein the alignment adjuster adjusts the phase of the signal according to the judge result.

14. The phase adjustment device of claim 13, wherein the alignment adjuster are used to adjust phases of a plurality of signals, the alignment detector detects the signals to determine if the signals are aligned with each other and generates a judge result, the alignment adjuster then adjusts the phase of at least one signal to align the phases of the signals.

15. The phase adjustment device of claim 13, wherein the alignment adjuster adjusts the phase of the signal by using different delays.
